(19) United States
(12) Patent Application Publication
(10) Pub. No.: US 2024/0332158 A1
(43) Pub. Date: Oct. 3, 2024

(54) ELECTRONIC DEVICE AND METHOD OF MANUFACTURING THE SAME

(71) Applicant: InnoLux Corporation, Miao-Li County (TW)

(72) Inventors: Ker-Yih KAO, Miao-Li County (TW); Yen-Fu LIU, Miao-Li County (TW); Wen-Hsiang LIAO, Miao-Li County (TW); Te-Hsun LIN, Miao-Li County (TW); Ju-Li WANG, Miao-Li County (TW); Dong-Yan YANG, Miao-Li County (TW); Ming-Hsien SHIH, Miao-Li County (TW); Cheng-Tse TSAI, Miao-Li County (TW)

(21) Appl. No.: 18/598,066

(22) Filed: Mar. 7, 2024

Related U.S. Application Data
(60) Provisional application No. 63/493,329, filed on Mar. 31, 2023.

(30) Foreign Application Priority Data
Jan. 5, 2024 (CN) 202410020986.2

(51) Int. Cl. H01L 23/498; H01L 21/48; H01L 21/56; H01L 21/683; H01L 23/00; H01L 23/31; H01L 25/16; H01L 25/18

(52) U.S. Cl. CPC H01L 23/49838; H01L 21/4853; H01L 21/563; H01L 21/6835; H01L 23/3128; H01L 24/13; H01L 24/16; H01L 24/32; H01L 24/73; H01L 24/81; H01L 24/83; H01L 24/92; H01L 25/16; H01L 25/18; H01L 2221/68345; H01L 2224/13105; H01L 2224/13111; H01L 2224/13139; H01L 2224/13144; H01L 2224/13147; H01L 2224/13155; H01L 2224/16227; H01L 2224/32225; H01L 2224/73204; H01L 2224/81005; H01L 2224/83005; H01L 2224/92125

(57) ABSTRACT

An electronic device is provided. The electronic device includes a chip, a redistribution structure, a contact pad, a buffer layer, and a first connection pad. The redistribution structure is electrically connected to the chip. The redistribution structure includes a metal pad, and the metal pad is disposed opposite to the chip. The contact pad is disposed on the metal pad. The buffer layer is disposed on the redistribution structure and includes an opening. The opening exposes at least a portion of the contact pad. The first connection pad is disposed on the contact pad and extends in the opening. Moreover, in a normal direction of the chip, the metal pad, the contact pad and the first connection pad overlap. A method of manufacturing an electronic device is also provided.

### CROSS REFERENCE TO RELATED APPLICATIONS

This application claims the benefit of China Application No. 202410020986.2, filed Jan. 5, 2024, which claims the benefit of provisional Application No. 63/493,329 filed Mar. 31, 2023, the entirety of which are incorporated by reference herein.

### BACKGROUND

### Technical Field

The present disclosure is related to an electronic device, and in particular it is related to a connection structure of an electronic device and a method of manufacturing the same.

### Description of the Related Art

Fan-out packaging, such as fan-out panel level package (FOPLP) or fan-out wafer level package (FOWLP) technology, can increase the integration density of electronic components (e.g., transistors, diodes, resistors, capacitors, etc.) in a given area. It has been widely used in the production and manufacturing of electronic devices in recent years.

However, a fan-out packaging structure has many interface integration structures of heterogeneous materials (for example, the interface between the redistribution layer (RDL) and the conductive pad, or under bump metallurgy (UBM) area, etc.), and the interface between heterogeneous materials is prone to problems such as delamination or peeling due to the presence of large amounts of stress.

As described above, developing packaging structures that can improve the reliability of electronic devices (for example, improving the strength of the connection structure between interfaces) is still one of the current research topics in the industry.

### SUMMARY

In accordance with some embodiments of the present disclosure, an electronic device is provided. The electronic device includes a chip, a redistribution structure, a contact pad, a buffer layer, and a first connection pad. The redistribution structure is electrically connected to the chip. The redistribution structure includes a metal pad, and the metal pad is disposed opposite to the chip. The contact pad is disposed on the metal pad. The buffer layer is disposed on the redistribution structure and includes an opening. The opening exposes at least a portion of the contact pad. The first connection pad is disposed on the contact pad and extends in the opening. Moreover, in a normal direction of the chip, the metal pad, the contact pad and the first connection pad overlap.

In accordance with some other embodiments of the present disclosure, a method of manufacturing an electronic device is provided. The method includes providing a substrate. The method includes forming a redistribution structure on the substrate. The redistribution structure includes a metal pad. The method includes forming a chip on the redistribution structure. The metal pad is disposed opposite to the chip. The method includes removing the substrate and flipping over the redistribution structure and the chip formed thereon. The method includes forming a contact pad on the metal pad. The method includes forming a buffer layer on the redistribution structure, and forming an opening in the buffer layer. The opening exposes at least a portion of the contact pad. The method includes forming a first connection pad on the contact pad and extending in the opening. Moreover, in a normal direction of the chip, the metal pad, the contact pad and the first connection pad overlap.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A to 1I are cross-sectional diagrams of an electronic device in different stages of the manufacturing process in accordance with some embodiments of the present disclosure;

FIG. 2 is a cross-sectional diagram of a contact pad of an electronic device in accordance with some embodiments of the present disclosure;

FIGS. 3A to 3D are cross-sectional diagrams of an electronic device in different stages of the manufacturing process in accordance with some embodiments of the present disclosure;

FIG. 4A and FIG. 4B are cross-sectional diagrams of an electronic device in different stages of the manufacturing process in accordance with some embodiments of the present disclosure;

FIGS. 5A to 5C are partial cross-sectional diagrams of an electronic device in accordance with some embodiments of the present disclosure;

FIGS. 6A to 6C are partial cross-sectional diagrams of an electronic device in accordance with some embodiments of the present disclosure;

FIG. 7A is a top-view diagram of an electronic device in accordance with some embodiments of the present disclosure;

FIG. 7B is a cross-sectional diagram of an electronic device corresponding to section line A1-A1′ of FIG. 7A in accordance with some embodiments of the present disclosure;

FIG. 8A and FIG. 8B are cross-sectional diagrams of an electronic device in different stages of the manufacturing process in accordance with some embodiments of the present disclosure;

FIG. 9A and FIG. 9B are top-view diagrams of an electronic device in accordance with some embodiments of the present disclosure;

FIGS. 10A to 10C are cross-sectional diagrams of an electronic device in different stages of the manufacturing process in accordance with some embodiments of the present disclosure.

### DETAILED DESCRIPTION

The electronic device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, an electronic device is provided, including connection structures configured in a specific manner (for example, including metal pads, contact pads, and connection pads of the redistribution structure), which can alleviate excessive concentration of stress on the joint surface when the connection structures are joined, causing problems such as peeling or breakage. Therefore, the structural strength and reliability of the electronic device can be improved.

In accordance with the embodiments of the present disclosure, the electronic device may include a power module, a semiconductor packaging device, a display device, a backlight device, an antenna device, a touch device, a sensing device, a wearable device, a vehicle device, a battery device, or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, another suitable material, or a combination thereof. The electronic device may include electronic components. The electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro light-emitting diode (micro LED) or a quantum dot light-emitting diode (quantum LED), but it is not limited thereto. In accordance with some embodiments, the electronic device may include a panel and/or a backlight module. The panel may include, for example, a liquid-crystal panel or another self-luminous panel, but it is not limited thereto. The tiled device may be, for example, a display tiled device or an antenna tiled device, but it is not limited thereto. It should be understood that the electronic device can be any permutation and combination of the above, but it is not limited thereto.

In accordance with the embodiments of the present disclosure, the provided method of manufacturing the electronic device can be applied, for example, to a wafer-level package (WLP) or panel-level package (PLP) process, and a chip-first process or a chip-last/RDL first process may be used, which will be explained in further detail below. The electronic device referred to in the present disclosure may include a system on package (SoC), a system in package (SiP), an antenna in package (AiP), or a combination thereof, but it is not limited thereto.

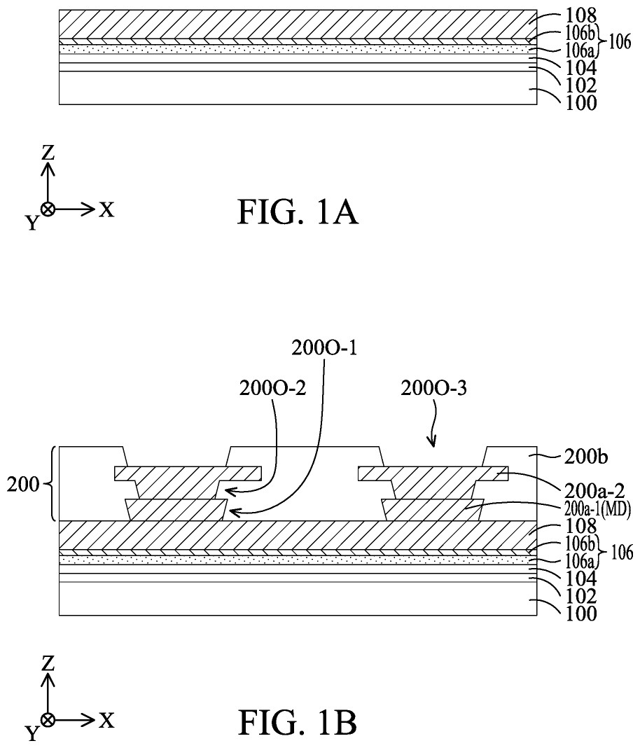

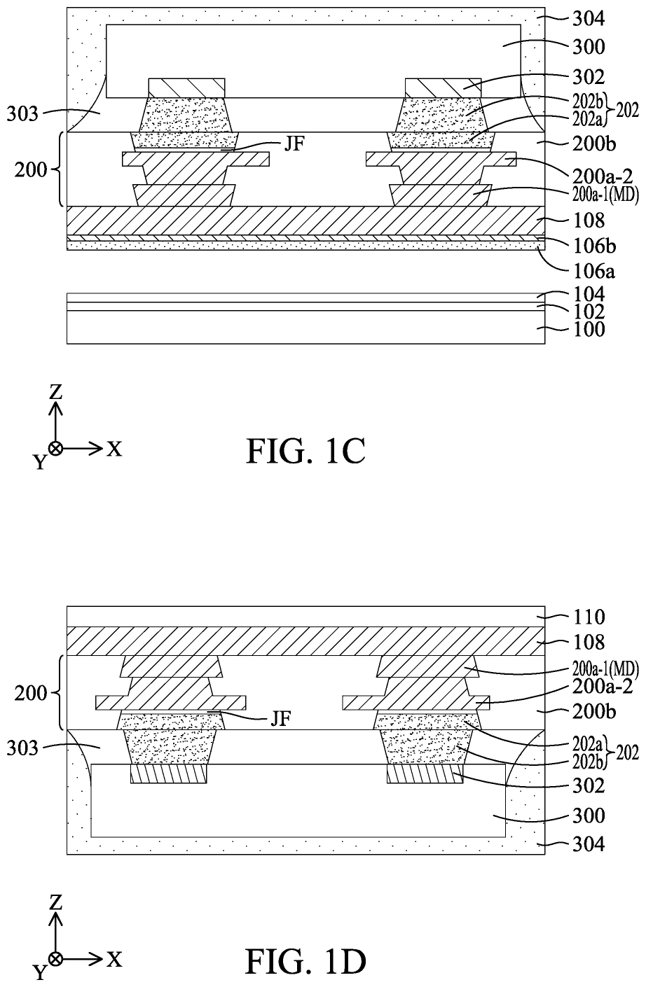

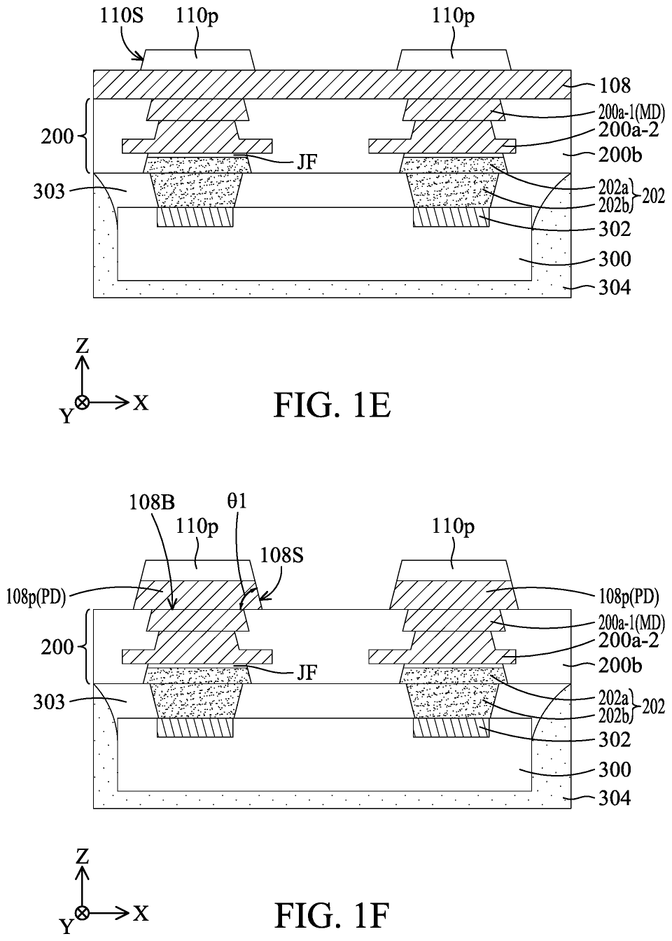

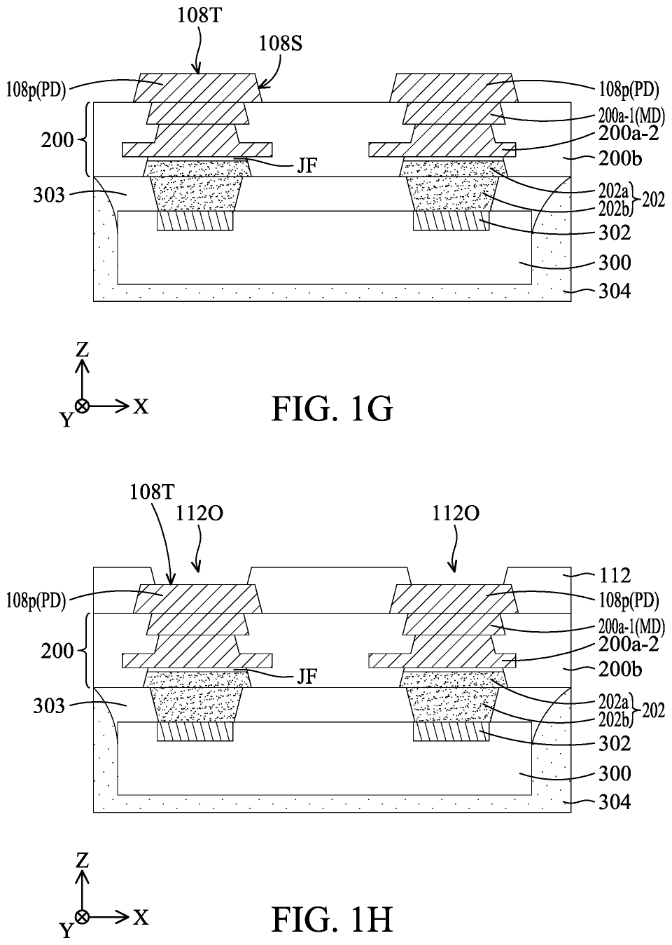

Please refer to FIGS. 1A to 1I, which are cross-sectional diagrams of an electronic device 10A in different stages of the manufacturing process in accordance with some embodiments of the present disclosure. It should be understood that, in accordance with some embodiments, additional operations may be provided before, during, and/or after the method of manufacturing the electronic device 10. In accordance with some embodiments, some of the operations described may be replaced or deleted. In accordance with some embodiments, the order of the operations may be interchangeable. Furthermore, some elements of the electronic device 10A may be omitted in the figure for clarity, and only some elements are schematically illustrated. In accordance with some embodiments, additional features may be added to the electronic device 10A described below. In accordance with some other embodiments, some features of the electronic device 10A described below may be replaced or omitted.

First, referring to FIG. 1A, a substrate 100 is provided. In accordance with some embodiments, a buffer layer 102 may be formed on the substrate 100. The substrate 100 may be a carrier substrate. In accordance with some embodiments, the substrate 100 may include a glass carrier substrate, a ceramic carrier substrate, or another suitable substrate, but it is not limited thereto. In accordance with some embodiments, the substrate 100 may be a chip or a wafer, but it is not limited thereto.

The buffer layer 102 may alleviate the strain difference between the substrate 100 and the release layer 104. In accordance with some embodiments, the thermal expansion trend of the buffer layer 102 may be opposite to the thermal expansion trend of other film layers formed on the substrate 100, so the warpage of the substrate 100 can be slowed down. The thermal expansion coefficient (CTE) of the buffer layer 102 may be greater than or equal to 0.1 ppm/K and less than or equal to 10 ppm/K. In accordance with some embodiments, the material of the buffer layer 102 may include silicon nitride, silicon oxide, silicon oxynitride, another suitable buffer material, or a combination thereof, but it is not limited thereto. Furthermore, the buffer layer 102 may have a single-layer or multi-layer structure. In accordance with some embodiments, the buffer layer 102 may be formed by a spin coating process, a chemical vapor deposition (CVD) process, another suitable method, or a combination thereof. The chemical vapor deposition process may include, for example, a low pressure chemical vapor deposition (LPCVD), a low temperature chemical vapor deposition (LTCVD), a rapid thermal chemical vapor deposition (RTCVD), a plasma enhanced chemical vapor deposition (PECVD) or an atomic layer deposition. (ALD), etc., but it is not limited thereto. In accordance with some embodiments, the thickness of the buffer layer 102 may be greater than or equal to 0.1 micrometer (m) and less than or equal to 10 micrometer. In accordance with some embodiments, the buffer layer 102 may be formed on at least one side of the substrate 100, or the buffer layers 102 may be formed on opposite sides of the substrate 100 respectively.

Next, a release layer 104 may be formed on the substrate 100, and the release layer 104 may be disposed on the buffer layer 102. The release layer 104 may be removed together with the buffer layer 102 and the substrate 100 from the overlying structure (e.g., the conductive layer 106) formed in subsequent steps. The release layer 104 may include polymer-based materials, but it is not limited thereto. In accordance with some embodiments, the release layer 104 may include an epoxy resin-based thermal insulation material that loses its adhesion when heated, such as a thermal release tape (HRT), or a light-to-heat-conversion (LTHC) release coating. In accordance with some other embodiments, the release layer 104 may include ultra-violet (UV) glue that loses adhesion when exposed to UV light. In accordance with some embodiments, the release layer 104 may lose its adhesion through a laser peeling process. In accordance with some embodiments, the release layer 104 may be formed by a coating and curing process, a lamination process, another suitable process, or a combination thereof. In accordance with some embodiments, the step of forming the release layer 104 may be omitted. In other words, subsequent layers may be formed on the substrate 100.

A conductive layer 106 may be formed on the substrate 100. The conductive layer 106 may be disposed on the release layer 104, and the conductive layer 106 may serve as a seed layer. In accordance with some embodiments, the conductive layer 106 may have a composite structure, for example, including a first sub-layer 106a and a second sub-layer 106b formed on the first sub-layer 106a. In accordance with some embodiments, the first sub-layer 106a and the second sub-layer 106b may be a titanium (Ti) layer and a copper (Cu) layer respectively, but they are not limited thereto. In accordance with some embodiments, the conductive layer 106 may include tantalum, gold, nickel, aluminum, another suitable conductive material, or a combination thereof, but it is not limited thereto. In accordance with some embodiments, the conductive layer 106 may be formed by a physical vapor deposition (PVD) process, an electroplating process, an electroless plating process, another suitable method, or a combination thereof. The physical vapor deposition process may include, for example, a sputtering process, an evaporation process, a pulsed laser deposition, etc., but it is not limited thereto.

Next, a conductive layer 108 may be formed on the substrate 100, and the conductive layer 108 may be disposed on the conductive layer 106. In accordance with some embodiments, the material of the conductive layer 108 may include copper (Cu), titanium (Ti), aluminum (Al), tungsten (W), silver (Ag), gold (Au), tin (Sn), molybdenum (Mo), chromium (Cr), nickel (Ni), platinum (Pt), alloys of the aforementioned metals, another suitable conductive material or a combination thereof, but it is not limited thereto. In accordance with some embodiments, the conductive layer 108 may be formed by a physical vapor deposition process, an electroplating process, an electroless plating process, another suitable method, or a combination thereof. In accordance with some embodiments, the thickness of the conductive layer 108 may be greater than or equal to 3 μm and less than or equal to 20 μm.

Referring to FIG. 1B, a redistribution structure 200 may be formed on the substrate 100, and the redistribution structure 200 may be disposed on the conductive layer 108. The redistribution layer (RDL) 200 may have one or more dielectric layers and patterned conductive layers. For example, as shown in FIG. 1B, in accordance with some embodiments, the redistribution structure 200 may include a patterned conductive layer 200a-1 and a patterned conductive layer 200a-2 disposed thereon, and the redistribution structure 200 may include a dielectric layer 200b. In accordance with some embodiments, the dielectric layer 200b may be formed first, an opening 2000-1 may be formed in the dielectric layer 200b, and then the patterned conductive layer 200a-1 (as a metal pad MD) may be formed in the opening 2000-1 of the dielectric layer 200b. In accordance with some embodiments, the redistribution structure 200 may redistribute circuits and/or further increase the circuit fan-out area, or may improve the area of bonding pads, or different electronic elements may be electrically connected to each other through the redistribution structure 200. Furthermore, the redistribution structure 200 may be applied to wafer level chip scale package (WLCSP), wafer level package (WLP), panel level package (PLP) or another packaging method, but it is not limited thereto.

Specifically, a dielectric material (as a part of the dielectric layer 200b) may be formed on the conductive layer 108 first, and a portion of the dielectric material may be removed to form the opening 2000-1 that exposes the conductive layer 108. Then, the patterned conductive layer 200a-1 may be formed in the opening 2000-1. Thereafter, a dielectric material (as part of the dielectric layer 200b) may be formed on the patterned conductive layer 200a-1, and a portion of the dielectric material may be removed to form an opening 2000-2 that exposes the patterned conductive layer 200a-1. Then, the patterned conductive layer 200a-2 may be formed in the opening 2000-2. Next, a dielectric material (as part of the dielectric layer 200b) may be formed on the patterned conductive layer 200a-2 again, and a portion of the dielectric material may be removed to form an opening 2000-3 that exposes the patterned conductive layer 200a-2.

In accordance with some embodiments, the patterned conductive layer 200a-1 and the patterned conductive layer 200a-2 may include conductive materials, such as copper (Cu), titanium (Ti), aluminum (Al), tungsten (W), silver (Ag), gold (Au), tin (Sn), molybdenum (Mo), chromium (Cr), nickel (Ni), platinum (Pt), alloys of the aforementioned metals, another suitable conductive material or a combination thereof, but they are not limited thereto. In accordance with some embodiments, the patterned conductive layer 200a-1 and/or the patterned conductive layer 200a-2 may have a multi-layer structure (not illustrated). In accordance with some embodiments, the conductive material may be formed by a physical vapor deposition process, an electroplating process, an electroless plating process, another suitable method, or a combination thereof. Furthermore, the conductive material may be patterned through one or more photolithography processes and/or etching processes to form the patterned conductive layer 200a-1 and the patterned conductive layer 200a-2. In accordance with some embodiments, the photolithography process may include photoresist coating (e.g., spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

In accordance with some embodiments, the dielectric layer 200b may include a polymer dielectric insulating material, such as polybenzoxazole (PBO), polyimide, benzocyclobutene (BCB), another suitable polymeric dielectric material, or a combination thereof, but it is not limited thereto. In accordance with some other embodiments, the dielectric layer 200b may include silicon nitride, silicon oxide, silicon oxynitride, phosphosilicate glass (PSG), borosilicate glass (BSG), boron-doped phosphosilicate glass (BPSG), another suitable dielectric material, or a combination thereof, but it is not limited thereto. In accordance with some embodiments, the dielectric layer 200b may have a multi-layer structure (not illustrated). In accordance with some embodiments, the dielectric layer 200b may be formed by a coating process, a spin coating process, a chemical vapor deposition process, another suitable method, or a combination thereof. Furthermore, part of the dielectric material may be removed through one or more photolithography processes and/or etching processes to form the aforementioned opening 2000-1, opening 2000-2, and opening 2000-3.

It should be understood that, according to different embodiments, the redistribution structure 200 may include any suitable number of insulating layers and patterned conductive layers, such as one or more insulating layers and patterned conductive layers. If more insulating layers and patterned conductive layers are desired, the aforementioned steps and processes can be repeated. In addition, in the embodiments of the method of manufacturing the electronic device 10A, a chip last/RDL first process is adopted. That is, the redistribution structure 200 is formed first, but the present disclosure is not limited thereto. In accordance with some other embodiments, the method of manufacturing the electronic device may also adopt a chip first process, which will be described below.

Referring to FIG. 1C, a chip 300 may be formed on the redistribution structure 200. In accordance with some embodiments, a connection pad 202 may be formed between the chip 300 and the redistribution structure 200, and the chip 300 may be electrically connected to the redistribution structure 200 through the connection pad 202. As shown in FIG. 1C, the connection pad 202 may be disposed corresponding to the patterned conductive layer 200a-2 and a conductive element 302 of the chip 300. That is, in the normal direction of the chip 300 (the Z direction in the figure), the connection pad 202 may overlap the patterned conductive layer 200a-2 and the conductive element 302. In detail, in accordance with some embodiments, a first portion 202a of the connection pad 202 may be formed in the opening 2000-3 and be electrically connected to the patterned conductive layer 200a-2, and a second portion 202b of the connection pad 202 may be formed between the conductive element 302 of the chip 300 and the first portion 202a and be electrically connected to the chip 300.

In accordance with some embodiments, the chip 300 may include, for example, a known-good die (KGD), an integrated circuit chip (IC), a surface mount device (SMD), a diode chip, or another suitable electronic element, but it is not limited thereto.

In accordance with some embodiments, the material of the connection pad 202 may include tin, silver, lead-free tin, copper, gallium, nickel, gold, another suitable material or a combination thereof, but it is not limited thereto. In accordance with some embodiments, the chip 300 may be bonded to the patterned conductive layer 200a-2 through the connection pad 202 by using a reflow process, a fusion bonding process, a hybrid bonding process, a metal-to-metal bonding process, another suitable method, or a combination thereof. In accordance with some embodiments, there is a bonding interface JF at the joint position between the patterned conductive layer 200a-2 and the connection pad 202.

Next, a first insulating layer 303 may be formed between the chip 300 and the redistribution structure 200, and a second insulating layer 304 may be formed surrounding the chip 300. The second insulating layer 304 may be in contact with the first insulating layer 303 and the redistribution structure 200. The first insulating layer 303 and the second insulating layer 304 may reduce the influence of water and oxygen on the chip 300 from the external environment. The first insulation layer 303 and the second insulation layer 304 may be in contact with the surface of the chip 300. In accordance with some embodiments, the first insulation layer 303 and the second insulation layer 304 may have inclined surfaces, but they are not limited thereto.

In accordance with some embodiments, the first insulating layer 303 and the second insulating layer 304 may include molding compound, epoxy resin, another suitable encapsulating material, or a combination thereof, but they are not limited thereto. Furthermore, the materials of the first insulating layer 303 and the second insulating layer 304 may be the same or different. In accordance with some embodiments, the first insulating layer 303 and the second insulating layer 304 may be formed by a compression molding process, a transfer molding process, or another suitable method. In accordance with some embodiments, the first insulating layer 303 and the second insulating layer 304 may be in a liquid or semi-liquid form during a molding process and then solidified. In accordance with some embodiments, the first insulating layer 303 may be formed first, and then the second insulating layer 304 may be formed. In accordance with some other embodiments, the first insulation layer 303 and the second insulation layer 304 may be formed simultaneously.

In accordance with some embodiments, after the first insulating layer 303 and the second insulating layer 304 are formed, the release layer 104 may lose its adhesion, for example, through a laser peeling process, so that the conductive layer 106 and the structure (redistribution structure 200, chip 300, etc.) packaged and integrated on the conductive layer 106 may be separated from the release layer 104 and the substrate 100. In accordance with some embodiments, the conductive layer 106 may be removed through an etching process, which may include a dry etching process, a wet etching process, or another suitable etching process.

Referring to FIG. 1D, the substrate 100 may be removed, and the redistribution structure 200 and the chip 300 formed thereon may be flipped over to expose the surface of the conductive layer 108 originally located at the bottom.

Next, a photoresist layer 110 may be formed on the conductive layer 108. In accordance with some embodiments, the photoresist layer 110 may be formed through a coating and curing process, a lamination process, another suitable process, or a combination thereof.

Referring to FIG. 1E, a portion of the photoresist layer 110 may be removed to form a patterned photoresist layer 110p. The patterned photoresist layer 110p may define the profile of a subsequently formed patterned conductive layer 108p. In accordance with some embodiments, the patterned photoresist layer 110p may have an inclined side surface 110S. For example, the patterned photoresist layer 110p may have a trapezoidal shape, but it is not limited thereto. The photoresist layer 110 may be a positive photoresist material or a negative photoresist material. The photoresist material may be patterned through one or more photolithography processes and/or etching processes to form the patterned photoresist layer 110p.

Referring to FIG. 1F, the patterned photoresist layer 110p then may be used as a mask to remove the conductive layer 108 that is not covered by the patterned photoresist layer 110p to form a patterned conductive layer 108p (as a contact pad PD) on the metal pad MD. That is, the conductive layer 108 may be patterned to form contact pad PD. In accordance with some embodiments, the conductive layer 108 may be removed by an etching process, which may include a dry etching process, a wet etching process, or another suitable etching process. As shown in FIG. 1F, in accordance with some embodiments, the contact pad PD may have an inclined side surface 108S. For example, the contact pad PD may have a trapezoidal shape, but it is not limited thereto. Specifically, in accordance with some embodiments, there is an included angle θ1 between the side surface 108S and the bottom surface 108B of the contact pad PD, and the included angle θ1 may be in a range from about 40 degrees to about 85 degrees (40 degrees≤the included angle θ1≤85 degrees), or from about 45 degrees to about 80 degrees, such as 50 degrees, 55 degrees, 60 degrees, 65 degrees, 70 degrees or 75 degrees, but it is not limited thereto. In accordance with some embodiments, the patterned conductive layer 108p may be, for example, a back side under-bump metallization (BS UBM) layer.

Referring to FIG. 1G, after the contact pad PD is formed, the patterned photoresist layer 110p may be removed. After the patterned photoresist layer 110p is removed, the side surfaces 108S and the top surface 108T of the contact pad PD may be exposed. In accordance with some embodiments, the patterned photoresist layer 110p may be removed through a stripping process, an ashing process, or another suitable method.

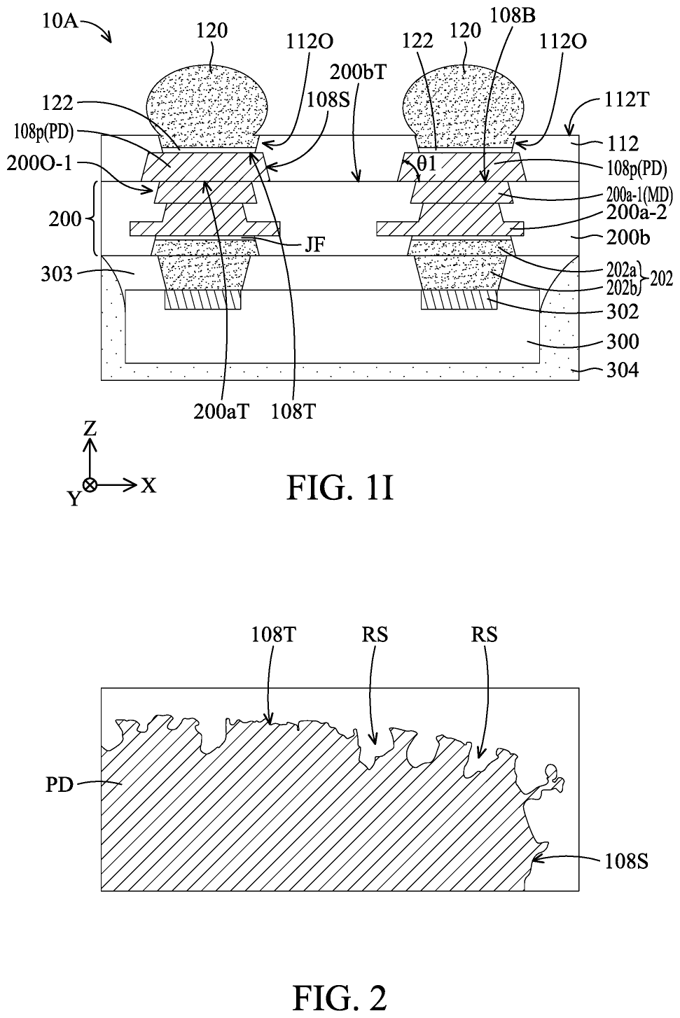

Next, in accordance with some embodiments, the surface of the patterned conductive layer 108p may be roughened through an etching process to form microstructures on the surface of the patterned conductive layer 108p, for example, a plurality of recesses (e.g., as shown in FIG. 2). In accordance with some embodiments, the etching process may include a dry etching process, a wet etching process, or another suitable etching process. In accordance with some embodiments, microstructures may also be formed on the surface of the conductive layer of the redistribution structure 200. Since the surface of the conductive layer is roughened, the adhesion ability of other film layers to the conductive layer can be improved. For example, the bonding ability between the dielectric layer 200b and the patterned conductive layer 200a may be improved.

Referring to FIG. 1H, a buffer layer 112 may be formed on the redistribution structure 200, and an opening 1120 may be formed in the buffer layer 112. The opening 1120 may expose at least a portion of the contact pad PD. For example, a portion of the top surface 108T of the contact pad PD may be exposed. The buffer layer 112 may be used to define the position of the subsequently formed connection pad 120, and the portion of the contact pad PD not covered by the buffer layer 112 may be used as the position for electrical connection with the subsequently formed connection pad 120. In accordance with some embodiments, the buffer layer 112 may be formed of a solder resist material. In accordance with some embodiments, the buffer layer 112 may include an insulating material, such as solder mask, epoxy resin, an inorganic material (e.g., silicon oxide, silicon nitride, silicon oxynitride, metal oxides, or a combination thereof), an organic polymer material (e.g., polyimide, benzocyclobutene, parylene, naphthalene polymer, fluorocarbon, or acrylate), another suitable insulating material or a combination thereof, but it is not limited thereto. In accordance with some embodiments, the buffer layer 112 may be formed by a coating process, a spin coating process, a chemical vapor deposition process, another suitable method, or a combination thereof. Furthermore, a portion of the buffer layer 1120 may be removed through one or more photolithography processes and/or etching processes. In accordance with some embodiments, the thickness of the buffer layer 112 may be greater than or equal to 15 μm and less than or equal to 40 μm. With the above design, the subsequent formation of the connection pad 120 can be facilitated.

Referring to FIG. 1I, a connection pad 120 then may be formed on the contact pad PD and extended in the opening 1120. The connection pad 120 may be disposed corresponding to the contact pad PD and the metal pad MD. That is, in the normal direction of the chip 300 (the Z direction in the figure), the metal pad MD, the contact pad PD and the connection pad 120 may overlap. In accordance with some embodiments, one end of the connection pad 120 may be electrically connected to the contact pad PD, and the other end may be electrically connected to a printed circuit board (PCB) (not illustrated), but the present disclosure is not limited thereto. In accordance with some embodiments, the connection pad 120 and the contact pad PD may react to form an intermediate layer 122, and at least a portion of the intermediate layer 122 may be disposed between the contact pad PD and the connection pad 120. In accordance with some embodiments, the intermediate layer 122 may be located at the bottom of the opening 1120.

In accordance with some embodiments, the material of the connection pad 120 may include tin, silver, lead-free tin, copper, nickel, gold, another suitable material or a combination thereof, but it is not limited thereto. In accordance with some embodiments, the connection pad 120 may be bonded to the contact pad PD through a reflow process, a fusion bonding process, a hybrid bonding process, a metal-to-metal bonding process, another suitable method, or a combination thereof.

In accordance with some embodiments, the intermediate layer 122 may be an intermetallic compound (IMC) formed by the reaction between the connection pad 120 and the contact pad PD. For example, the intermediate layer 122 may include Cu₆Sn₅, Cu₃Sn, Ag₃Sn, another suitable material, or a combination thereof, but it is not limited thereto. In accordance with some embodiments, the thickness of the intermetallic compound may be greater than or equal to 3 μm and less than or equal to 7 μm. In accordance with some embodiments, the thickness of the intermetallic compound is different from the thickness of the bonding interface JF. In accordance with some embodiments, the thickness of the intermetallic compound may be greater than the thickness of the bonding interface JF.

As shown in FIG. 1I, the formed electronic device 10A may include a chip 300 and a redistribution structure 200. The redistribution structure 200 may be electrically connected to the chip 300. The redistribution structure 200 may include a metal pad MD, and the metal pad MD may be disposed opposite to the chip 300. In accordance with some embodiments, the electronic device 10A may include a connection pad 202 disposed between the chip 300 and the redistribution structure 200, and the chip 300 may be electrically connected to the redistribution structure 200 through the connection pad 202. In accordance with some embodiments, the metal pad MD may be electrically connected to the chip 300 through the patterned conductive layer 200a-2, the connection pad 202 and a conductive element 302. In accordance with some embodiments, the connection pad 202 may have a first portion 202a disposed in the redistribution structure 200 and a second portion 202b disposed between the first portion 202a and the conductive element 302.

Furthermore, the electronic device 10A may include a contact pad PD, a buffer layer 112 and a connection pad 120. The contact pad PD may be disposed on the metal pad MD. The buffer layer 112 may be disposed on the redistribution structure 200 and include an opening 1120, and the opening 1120 may expose at least a portion of the contact pad PD. The connection pad 120 may be disposed on the contact pad PD and extend in the opening 1120. Moreover, in the normal direction of the chip 300 (the Z direction in the figure), the metal pad MD, the contact pad PD and the connection pad 120 may overlap. In accordance with some embodiments, the electronic device 10A may include an intermediate layer 122, and at least a portion of the intermediate layer 122 may be disposed between the contact pad PD and the connection pad 120.

Furthermore, as mentioned above, in accordance with some embodiments, there is an included angle θ1 between the side surface 108S and the bottom surface 108B of the contact pad PD, and the included angle θ1 may be in a range from about 40 degrees to about 85 degrees (40 degrees≤the angle θ1≤85 degrees), or from about 45 degrees to about 80 degrees, for example, 50 degrees, 55 degrees, 60 degrees, 65 degrees, 70 degrees or 75 degrees, but it is not limited thereto.

Based on the foregoing, in accordance with some embodiments, the surface of the conductive layer 108 may be roughened through an etching process. Therefore, in the formed electronic device 10A, the surface of the contact pad PD may have a plurality of recesses RS. FIG. 2 is a cross-sectional diagram of the contact pad PD of the electronic device 10A in accordance with some embodiments of the present disclosure. As shown in FIG. 2, in accordance with some embodiments, the recesses RS may be discontinuously disposed on the surface of the contact pad PD, and the recesses RS may have an irregular shape. In accordance with some embodiments, the recesses RS may be disposed on the top surface 108T and part of the side surface 108S of the contact pad PD. In accordance with some embodiments, the surface roughness (Ra) of the contact pad PD may be greater than or equal to 0.5 μm and less than or equal to 5 μm. The surface roughness (Ra) may be measured by first taking a reference line, which can be substantially parallel to the extension direction of the object to be measured, and then taking the vertical distance from at least 5 points above the reference line to the reference line and the vertical distance from at least 5 points below the reference line to the reference line. The average of these vertical distances then can be calculated, which is the surface roughness.

Please refer to FIG. 1I again. In accordance with some embodiments, the redistribution structure 200 may include a dielectric layer 200b, the metal pad MD may be disposed in the opening 2000-1 of the dielectric layer 200b, and the top surface 200aT of the metal pad MD and the top surface 200bT of dielectric layer 200b may be coplanar. In accordance with some embodiments, the top surface 108T of contact pad PD and top surface 112T of buffer layer 112 are non-coplanar. In accordance with some embodiments, the top surface 108T of the contact pad PD may be lower than the top surface 112T of the buffer layer 112. In other words, the interface between the contact pad PD and the connection pad 120 may be located below the top surface 112T of the buffer layer 112. It should be noted that with this configuration, the location where the contact pad PD and the connection pad 120 are joined is located below the interface between the buffer layer 112 and the connection pad 120, thereby alleviating excessive concentration of stress on the joint surface when the connection pad 120 and the contact pad PD are joined, causing problems such as peeling or breakage. Therefore, the structural strength and reliability of the electronic device 10A can be improved.

In addition, in accordance with some embodiments, the electronic device 10A may further include a first insulating layer 303 and a second insulating layer 304. The first insulating layer 303 may be disposed between the chip 300 and the redistribution structure 200. The second insulating layer 304 may surround the chip 300 and be in contact with the first insulating layer 303 and redistribution structure 200. In accordance with some embodiments, the first portion 202a of the connection pad 202 may be disposed in the redistribution structure 200, and the second portion 202b may be disposed in the first insulating layer 303.

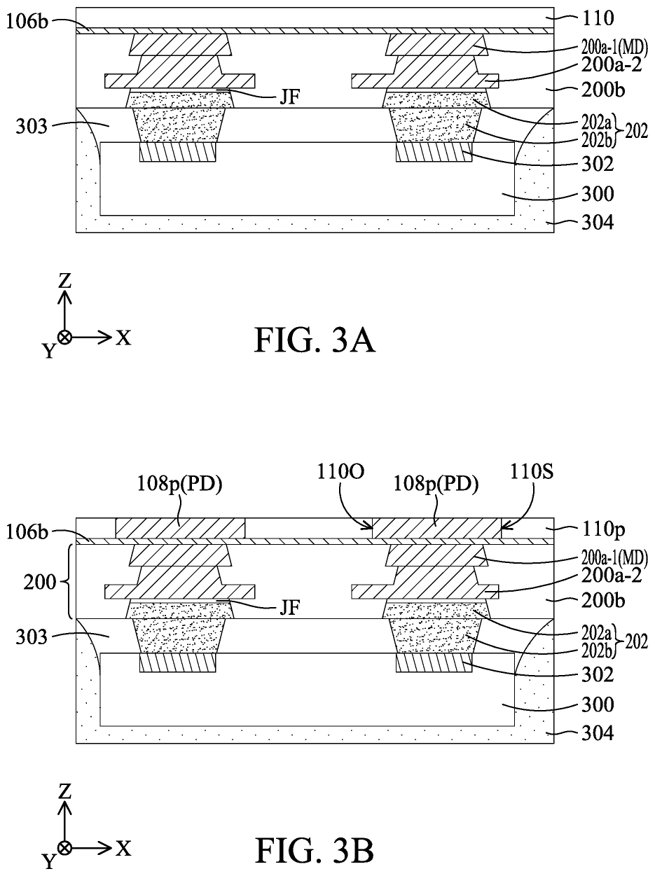

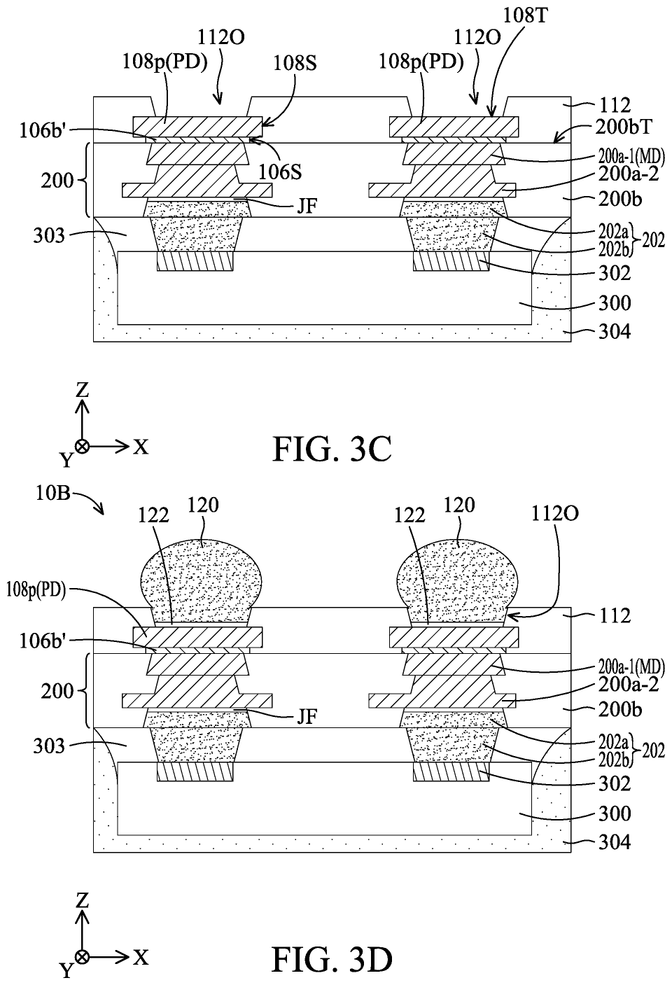

Please refer to FIGS. 3A to 3D, which are cross-sectional diagrams of an electronic device 10B in different stages of the manufacturing process in accordance with some other embodiments of the present disclosure. It should be understood that components or elements that are identical or similar to those mentioned above will be denoted by the same or similar numerals, and their materials, manufacturing methods and functions are the same or similar to those described above, and thus will not be repeated in the following description.

Please refer to FIG. 3A. In accordance with some embodiments, after the release layer 104 loses its adhesion through a laser peeling process, so that the conductive layer 106 and the structure packaged and integrated on the conductive layer 106 may be separated from the release layer 104 and the substrate 100, the first sub-layer 106a of the conductive layer 106 may be removed through an etching process, but the second sub-layer 106b may remain. Next, the redistribution structure 200 and the chip 300 formed thereon may be flipped over. Thereafter, the photoresist layer 110 may be formed on the second sub-layer 106b.

Referring to FIG. 3B, a portion of the photoresist layer 110 may be removed to form the patterned photoresist layer 110p. The patterned photoresist layer 110p may define the profile of the subsequently formed patterned conductive layer 108p. In this embodiment, the patterned photoresist layer 110p may have the side surface 110S that is substantially perpendicular to the second sub-layer 106b, but it is not limited thereto. Next, the patterned conductive layer 108p (contact pad PD) may be formed in an opening 1100 of the patterned photoresist layer 110p. The contact pad PD may be in contact with the second sub-layer 106b of the conductive layer 106.

Referring to FIG. 3C, the patterned photoresist layer 110p then may be removed, and the second sub-layer 106b not covered by the contact pad PD may be removed to form a patterned second sub-layer 106b′. As shown in FIG. 3C, in this embodiment, the contact pad PD may have the side surface 108S that is substantially perpendicular to the top surface 200bT of the dielectric layer 200b, but it is not limited thereto. In accordance with some embodiments, the side surface 1065 of the patterned second sub-layer 106b′ may be retracted inward compared to the side surface 108S of the contact pad PD. For example, compared to the side surface 108S, the side surface 106S retracted inward by a distance of 1 less than or equal to 1 μm, or less than or equal to 0.5 μm. In accordance with some other embodiments, the side surface 108S of the contact pad PD may be substantially aligned with the side surface 106S of the patterned second sub-layer 106b′, but it is not limited thereto. In accordance with some embodiments, the two side surfaces 106S of the patterned second sub-layer 106b′ may be retracted inward by an unequal degree. For example, one side may be retracted by 0.2 μm and the other side may be retracted by 0.3 μm, but they are not limited thereto.

Next, the buffer layer 112 may be formed on the redistribution structure 200, and the opening 1120 may be formed in the buffer layer 112. The opening 1120 may expose at least a portion of the contact pad PD, for example, may expose a portion of the top surface 108T of the contact pad PD. The buffer layer 112 may be used to define the position of the subsequently formed connection pad 120, and the portion of the contact pad PD not covered by the buffer layer 112 may be used as the position for electrical connection with the subsequently formed connection pad 120.

Referring to FIG. 3D, the connection pad 120 then may be formed on the contact pad PD and extend in the opening 1120. The connection pad 120 may be disposed corresponding to the contact pad PD and the metal pad MD. That is, in the normal direction of the chip 300 (the Z direction in the figure), the metal pad MD, the contact pad PD and the connection pad 120 may overlap. Furthermore, in this embodiment, in the normal direction of the chip 300 (the Z direction in the figure), the connection pad 120 may also overlap the patterned second sub-layer 106b′. In accordance with some embodiments, the connection pad 120 may react with the contact pad PD to form the intermediate layer 122, and at least a portion of the intermediate layer 122 is disposed between the contact pad PD and the connection pad 120. In accordance with some embodiments, the intermediate layer 122 may be located at the bottom of the opening 1120.

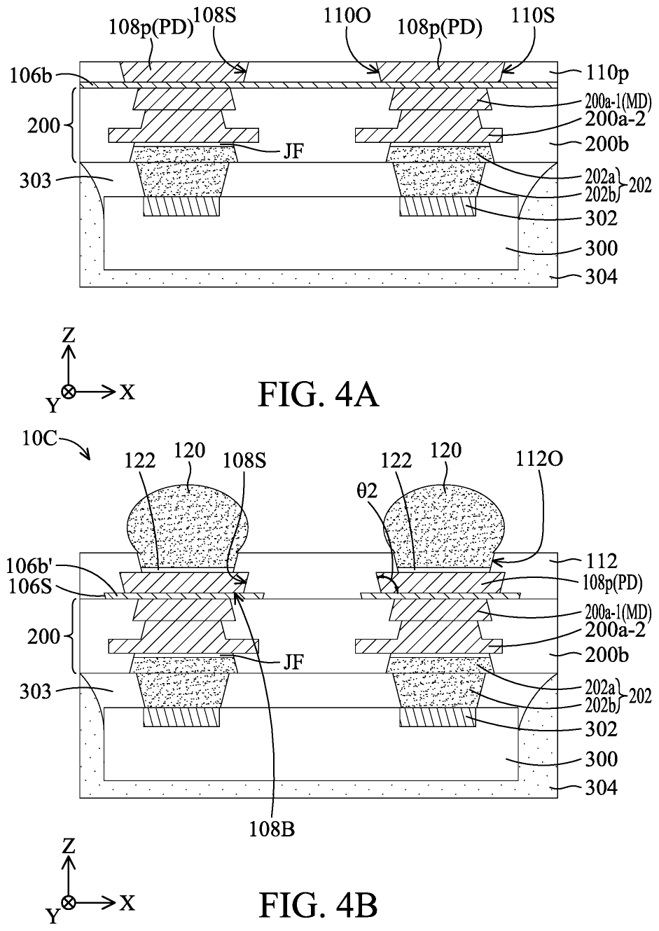

Please refer to FIG. 4A and FIG. 4B, which are cross-sectional diagrams of an electronic device 10C in different stages of the manufacturing process in accordance with some other embodiments of the present disclosure. It should be understood that components or elements that are identical or similar to those mentioned above will be denoted by the same or similar numerals, and their materials, manufacturing methods and functions are the same or similar to those described above, and thus will not be repeated in the following description.

Please refer to FIG. 4A. In this embodiment, the patterned photoresist layer 110p may have the side surface 110S that is not perpendicular to the second sub-layer 106b. That is, the patterned photoresist layer 110p may have an inclined side surface 110S. Next, the patterned conductive layer 108p (contact pad PD) may be formed in the opening 1100 of the patterned photoresist layer 110p. The contact pad PD may be in contact with the second sub-layer 106b of the conductive layer 106. In this embodiment, the contact pad PD may have an inclined side surface 108S, but it is not limited thereto.

Referring to FIG. 4B, then, the patterned photoresist layer 110p may be removed, and the second sub-layer 106b not covered by the contact pad PD may be removed to form the patterned second sub-layer 106b′. Thereafter, the buffer layer 112 may be formed on the redistribution structure 200, and the opening 1120 may be formed in the buffer layer 112. The opening 1120 may expose at least a portion of the contact pad PD. Furthermore, the connection pad 120 may be formed on the contact pad PD and extend in the opening 1120. The connection pad 120 may react with the contact pad PD to form the intermediate layer 122, and at least a portion of the intermediate layer 122 may be disposed between the contact pad PD and the connection pad 120. In accordance with some embodiments, the intermediate layer 122 may be located at the bottom of the opening 1120.

As shown in FIG. 4B, in this embodiment, the contact pad PD may have an inclined side surface 108S. For example, the contact pad PD may have an inverted trapezoidal shape, but it is not limited thereto. Specifically, in this embodiment, there is an included angle θ2 between the side surface 108S and the bottom surface 108B of the contact pad PD. The included angle θ2 may be in a range from about 95 degrees to about 140 degrees (95 degrees≤the included angle θ2≤140 degrees), or from about 100 degrees to about 135 degrees, for example, 105 degrees, 110 degrees, 115 degrees, 120 degrees, 125 degrees or 130 degrees, but it is not limited thereto. Furthermore, in this embodiment, compared to the side surface 108S of the contact pad PD, the side surface 106S of the patterned second sub-layer 106b′ may be protruded. For example, the side surface 106S may protrude from the side surface 108S by a distance of less than or equal to 1 μm, or less than or equal to 0.5 μm.

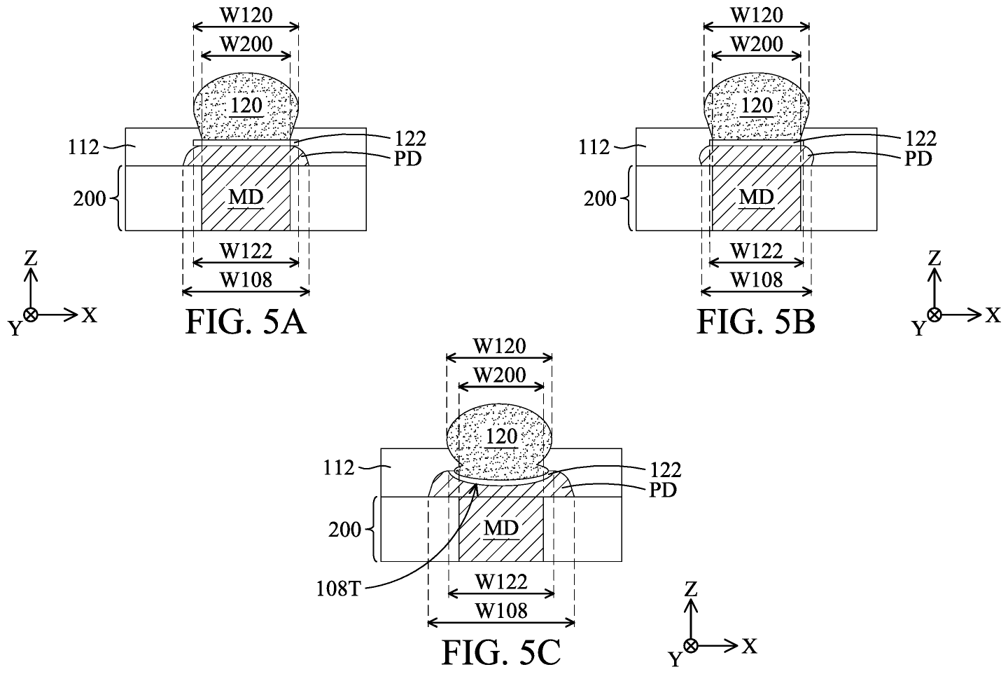

Please refer to FIGS. 5A to 5C, which are partial cross-sectional diagrams of an electronic device in accordance with some embodiments of the present disclosure. As shown in FIG. 5A, the buffer layer 112 may cover the contact pad PD, and the buffer layer 112 may be in contact with the contact pad PD, the intermediate layer 122 and the connection pad 120. The top surface width of the contact pad PD may be smaller than the bottom surface width. That is, the contact pad PD may have a trapezoidal shape. Furthermore, the contact pad PD may have an arc-shaped top corner. The intermediate layer 122 may partially cover the top surface of the contact pad PD. The width W108 of the contact pad PD may be greater than the width W120 of the connection pad 120. The width W108 of the contact pad PD may be greater than the width W200 of the metal pad MD. The width W108 of the contact pad PD may be greater than the width W122 of the intermediate layer 122. Moreover, the width W120 of the connection pad 120 may be substantially the same as the width W122 of the intermediate layer 122. It should be noted that with the foregoing configuration, the bonding strength and structural reliability between the connection pad 120, the intermediate layer 122, the contact pad PD and the metal pad MD may be improved, and the risk of the structure breaking along the brittle material during bonding may be reduced.

In accordance with the embodiments of the present disclosure, the width W108 refers to the maximum width of the contact pad PD in the direction perpendicular to the normal direction of the chip 300 (e.g., the X direction in the figure); the width W120 refers to the maximum width of the connection pad 120 in the direction perpendicular to the normal direction of the chip 300; the width W200 refers to the maximum width of the metal pad MD in the direction perpendicular to the normal direction of the chip 300; and the width W122 refers to the maximum width of the intermediate layer 122 in the direction perpendicular to the normal direction of the chip 300.

Furthermore, it should be understood that, in accordance with the embodiments of the present disclosure, a scanning electron microscope (SEM), an optical microscope (OM), a film thickness profiler (α-step), an ellipsometer or another suitable method may be used to measure the width, thickness or height of each element, or spacing or distance between elements. Specifically, in accordance with some embodiments, a scanning electron microscope may be used to obtain a cross-sectional image including the elements to be measured, and the width, thickness or height of each element, or spacing or distance between elements in the image can be measured.

As shown in FIG. 5B, the buffer layer 112 may cover the contact pad PD, and the buffer layer 112 may be in contact with the contact pad PD, the intermediate layer 122 and the connection pad 120. The top surface width of the contact pad PD may be greater than the bottom surface width. That is, the contact pad PD may have an inverted trapezoidal shape. The intermediate layer 122 may partially cover the top surface of the contact pad PD. The width W108 of the contact pad PD may be greater than the width W120 of the connection pad 120. The width W108 of the contact pad PD may be greater than the width W200 of the metal pad MD. The width W108 of the contact pad PD may be greater than the width W122 of the intermediate layer 122. Furthermore, the width W120 of the connection pad 120 may be greater than the width W122 of the intermediate layer 122. It should be noted that with the foregoing configuration, the bonding strength and structural reliability between the connection pad 120, the intermediate layer 122, the contact pad PD and the metal pad MD may be improved, and the risk of the structure breaking along the brittle material during bonding may be reduced.

As shown in FIG. 5C, the buffer layer 112 may cover the contact pad PD, and the buffer layer 112 may be in contact with the contact pad PD, the intermediate layer 122 and the connection pad 120. The top surface width of the contact pad PD may be smaller than the bottom surface width. That is, the contact pad PD may have a trapezoidal shape. In this embodiment, the contact pad PD may have a curved surface, such as curved top surface 108T. Furthermore, the intermediate layer 122 may also have a curved surface. In accordance with some embodiments, the intermediate layer 122 may partially overlap the contact pad PD in the direction perpendicular to the normal direction of the chip 300 (e.g., the X direction in the figure). The intermediate layer 122 may partially cover the top surface of the contact pad PD. The width W108 of the contact pad PD may be greater than the width W120 of the connection pad 120. The width W108 of the contact pad PD may be greater than the width W200 of the metal pad MD. The width W108 of the contact pad PD may be greater than the width W122 of the intermediate layer 122. Furthermore, the width W120 of the connection pad 120 may be substantially the same as the width W122 of the intermediate layer 122. It should be noted that with the foregoing configuration, the bonding strength and structural reliability between the connection pad 120, the intermediate layer 122, the contact pad PD and the metal pad MD may be improved, and the risk of the structure breaking along the brittle material during bonding may be reduced.

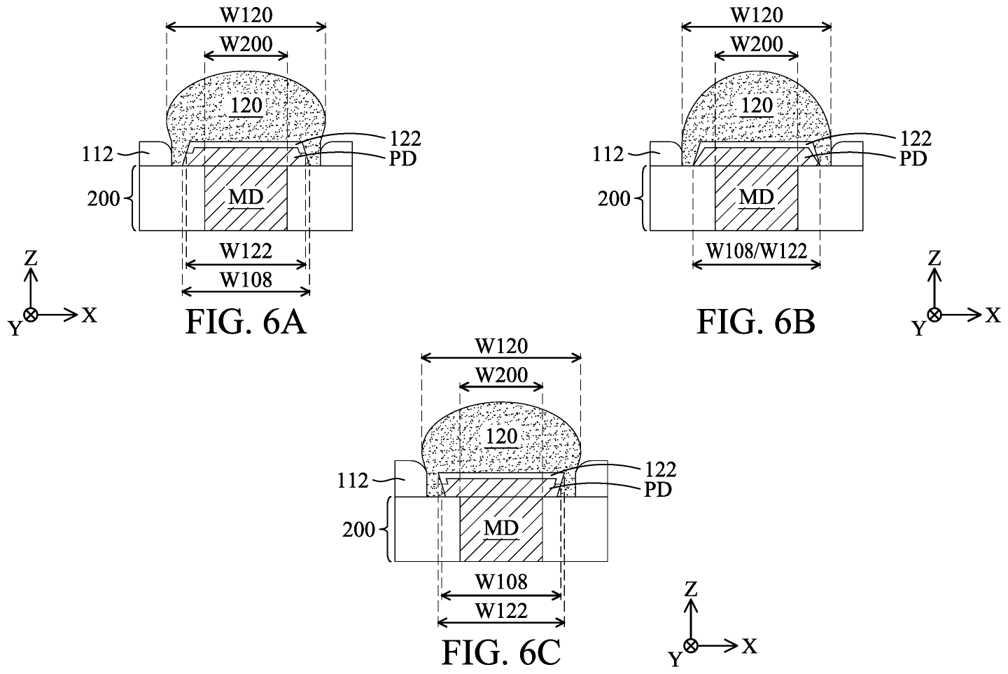

Please refer to FIGS. 6A to 6C, which are partial cross-sectional diagrams of an electronic device in accordance with some other embodiments of the present disclosure. As shown in FIG. 6A, in this embodiment, the buffer layer 112 may not cover the contact pad PD. The buffer layer 112 may be separated from the contact pad PD and the intermediate layer 122 by a certain distance. The buffer layer 112 may be in contact with the connection pad 120. The connection pad 120 may cover at least a portion of the side surface of the contact pad PD. The connection pad 120 may be in contact with the redistribution structure 200 (e.g., the dielectric layer 200b). Furthermore, the buffer layer 112 may have an arc-shaped top corner. The top surface width of the contact pad PD may be smaller than the bottom surface width. That is, the contact pad PD may have a trapezoidal shape. The intermediate layer 122 may partially cover the top surface and side surfaces of the contact pad PD. The width W108 of the contact pad PD may be smaller than the width W120 of the connection pad 120. The width W108 of the contact pad PD may be greater than the width W200 of the metal pad MD. The width W108 of the contact pad PD may be larger than the width W122 of the intermediate layer 122. Furthermore, the width W120 of the connection pad 120 may be greater than the width W122 of the intermediate layer 122. It should be noted that with the foregoing configuration, the bonding strength and structural reliability between the connection pad 120, the intermediate layer 122, the contact pad PD and the metal pad MD may be improved, and the risk of the structure breaking along the brittle material during bonding may be reduced.

As shown in FIG. 6B, in this embodiment, the buffer layer 112 may not cover the contact pad PD. The buffer layer 112 may be separated from the contact pad PD and the intermediate layer 122 by a certain distance. The buffer layer 112 may be in contact with the connection pad 120, and the connection pad 120 may be in contact with the redistribution structure 200 (e.g., the dielectric layer 200b). The top surface width of the contact pad PD may be smaller than the bottom surface width. That is, the contact pad PD may have a trapezoidal shape. The intermediate layer 122 may substantially entirely cover the top surface and the side surfaces of the contact pad PD. The width W108 of the contact pad PD may be smaller than the width W120 of the connection pad 120. The width W108 of the contact pad PD may be greater than the width W200 of the metal pad MD. The width W108 of the contact pad PD may be substantially equal to the width W122 of the intermediate layer 122. Furthermore, the width W120 of the connection pad 120 may be greater than the width W122 of the intermediate layer 122. It should be noted that with the aforementioned configuration, the bonding strength and structural reliability between the connection pad 120, the intermediate layer 122, the contact pad PD and the metal pad MD may be improved, and the risk of the structure breaking along the brittle material during bonding may be reduced.

As shown in FIG. 6C, in this embodiment, the buffer layer 112 may not cover the contact pad PD. The buffer layer 112 may be separated from the contact pad PD and the intermediate layer 122 by a certain distance. The buffer layer 112 may be in contact with the connection pad 120, and the connection pad 120 may cover at least a portion of the side surface of the contact pad PD. The connection pad 120 may be in contact with the redistribution structure 200 (e.g., the dielectric layer 200b). The top surface width of the contact pad PD may be greater than the bottom surface width. That is, the contact pad PD may have an inverted trapezoidal shape. The intermediate layer 122 may partially cover the top surface and side surfaces of the contact pad PD. The width W108 of the contact pad PD may be smaller than the width W120 of the connection pad 120. The width W108 of the contact pad PD may be greater than the width W200 of the metal pad MD. The width W108 of the contact pad PD may be greater than the width W122 of the intermediate layer 122. Furthermore, the width W120 of the connection pad 120 may be greater than the width W122 of the intermediate layer 122. It should be noted that with the aforementioned configuration, the bonding strength and structural reliability between the connection pad 120, the intermediate layer 122, the contact pad PD and the metal pad MD may be improved, and the risk of the structure breaking along the brittle material during bonding may be reduced.

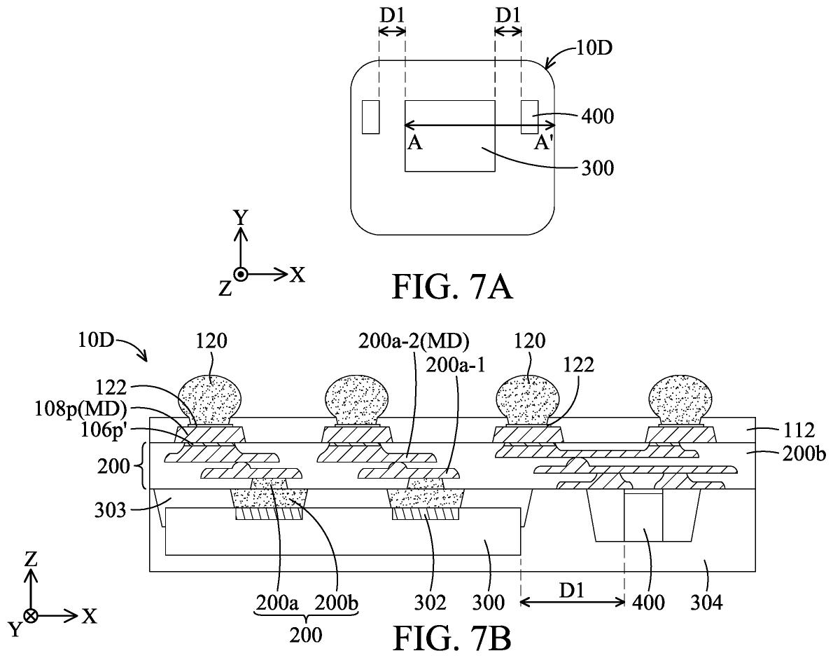

Please refer to FIG. 7A and FIG. 7B. FIG. 7A is a top-view diagram of an electronic device 10D in accordance with some embodiments of the present disclosure. FIG. 7B is a cross-sectional diagram of the electronic device 10D corresponding to section line A1-A1′ of FIG. 7A in accordance with some embodiments of the present disclosure.

As shown in FIG. 7A and FIG. 7B, in accordance with some embodiments, the electronic device 10D may further include an electronic component 400, and the electronic component 400 may be integrated and packaged together with the chip 300 in the electronic device 10D. In accordance with some embodiments, the electronic component 400 may include a resistor, a capacitor, an inductor, a transistor and another suitable component, but it is not limited thereto. Furthermore, the electronic component 400 may be adjacent to the chip 300 and in contact with the second insulating layer 304. The electronic component 400 and the chip 300 may be separated by a distance of D1, and the distance D1 may be greater than or equal to 1 millimeter (the distance D1≥1 mm). It should be noted that if the distance between the electronic component 400 and the chip 300 is too close (for example, less than 1 mm), mutual signal interference or shielding problems may occur between the electronic component 400 and the chip 300.

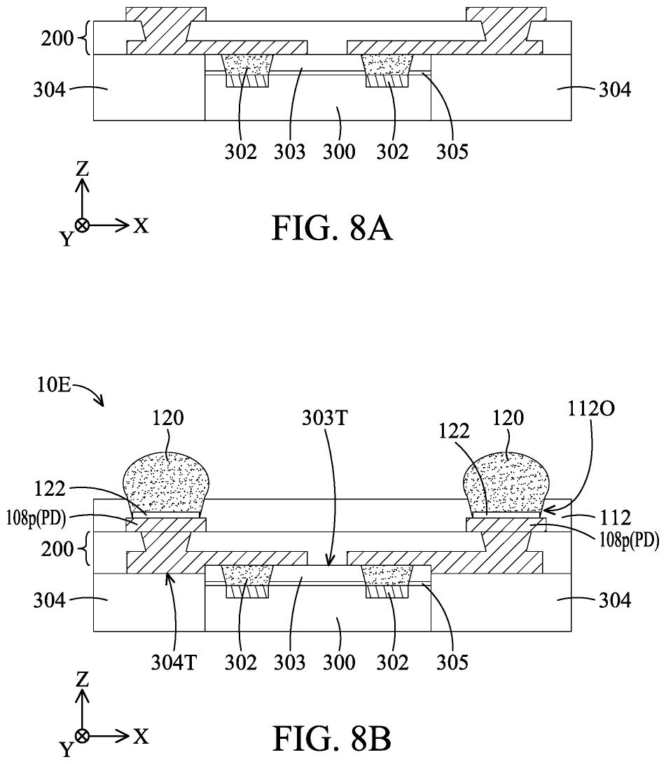

Please refer to FIG. 8A and FIG. 8B, which are cross-sectional diagrams of an electronic device 10E in different stages of the manufacturing process in accordance with some other embodiments of the present disclosure. In the embodiment of the method of manufacturing the electronic device 10E, a chip first process may be adopted.

Referring to FIG. 8A, the chip 300 may be first packaged in the first insulating layer 303 and the second insulating layer 304, and then the redistribution structure 200 may be formed on the chip 300. The redistribution structure 200 may be electrically connected to the chip 300 through the conductive element 302. In detail, a passivation layer 305 may be formed on the chip 300, then the first insulating layer 303 may be formed on the chip 300 and the passivation layer 305, and the second insulating layer 304 may be formed surrounding the chip 300. Furthermore, a portion of the first insulating layer 303 may be removed to expose the conductive elements 302 of the chip 300, and then the redistribution structure 200 may be formed.

Referring to FIG. 8B, the patterned conductive layer 108p (the contact pad PD) and the buffer layer 112 may be formed on the redistribution structure 200, and the opening 1120 may be formed in the buffer layer 112. The connection pad 120 may be formed on the contact pad PD and extend in the opening 1120. Similarly, the connection pad 120 may react with the contact pad PD to form the intermediate layer 122, and at least a portion of the intermediate layer 122 may be disposed between the contact pad PD and the connection pad 120. In accordance with some embodiments, the top surface 303T of the first insulating layer 303 may be higher than the top surface 304T of the second insulating layer 304, and the redistribution structure 200 may therefore extend downward to increase bonding stability by being non-coplanar with the first insulating layer 303.

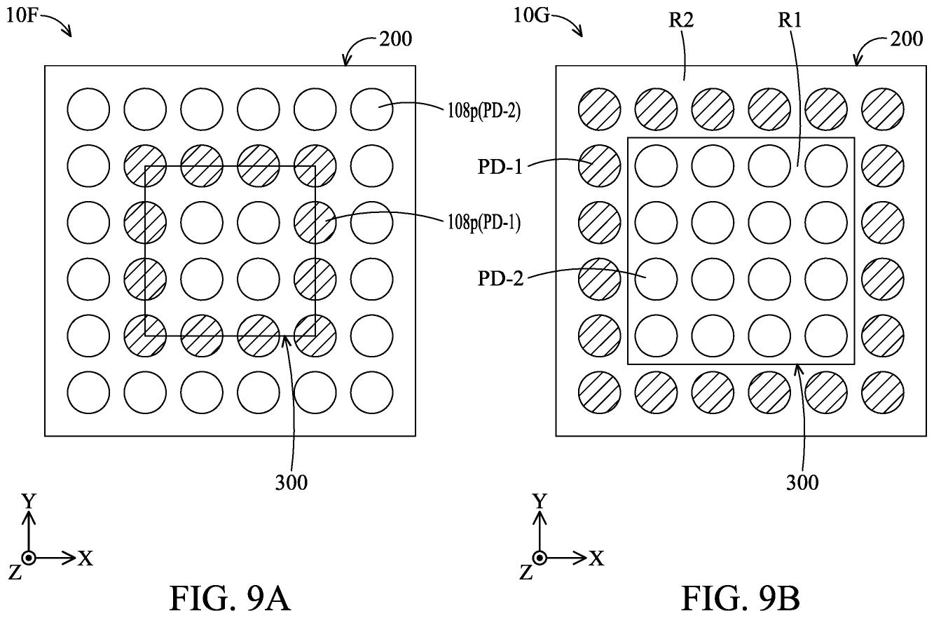

Please refer to FIG. 9A and FIG. 9B, which are top-view diagrams of an electronic device 10F and an electronic device 10G in accordance with some embodiments of the present disclosure, respectively.

As shown in FIG. 9A, the chip 300 of the electronic device 10F may have at least 4 edges. The redistribution structure 200 may have the patterned conductive layers 108p (labeled as contact pads PD-1, for convenience of explanation) at the position overlapping the at least 4 edges of the chip 300, and optionally not have the contact pads protruding from the redistribution structure 200 (labeled as contact pads PD-2, for convenience of explanation) at other positions. With the above design, the risk of cracking of the connection pad 120 or the contact pad PD after the electronic device 10F is connected to an external component (e.g., a printed circuit board) may be reduced.

As shown in FIG. 9B, the electronic device 10G may have a first area R1 and a second area R2. The area where the chip 300 overlaps the redistribution structure 200 may be defined as the first area R1. The second area R2 may surround the first area. R1. The second region R2 may have the contact pads PD-1 protruding from the redistribution structure 200. The number of protruding contact pads PD-1 in the second region R2 may be greater than the number of protruding contact pads PD-1 in the first region R1. Through the above design, the risk of cracking of the connection pad 120 or the contact pad PD after the electronic device 10G is bonded to the printed circuit board may be reduced.

Please refer to 10A to 10C, which are cross-sectional diagrams of an electronic device 10H in different stages of the manufacturing process in accordance with some other embodiments of the present disclosure.

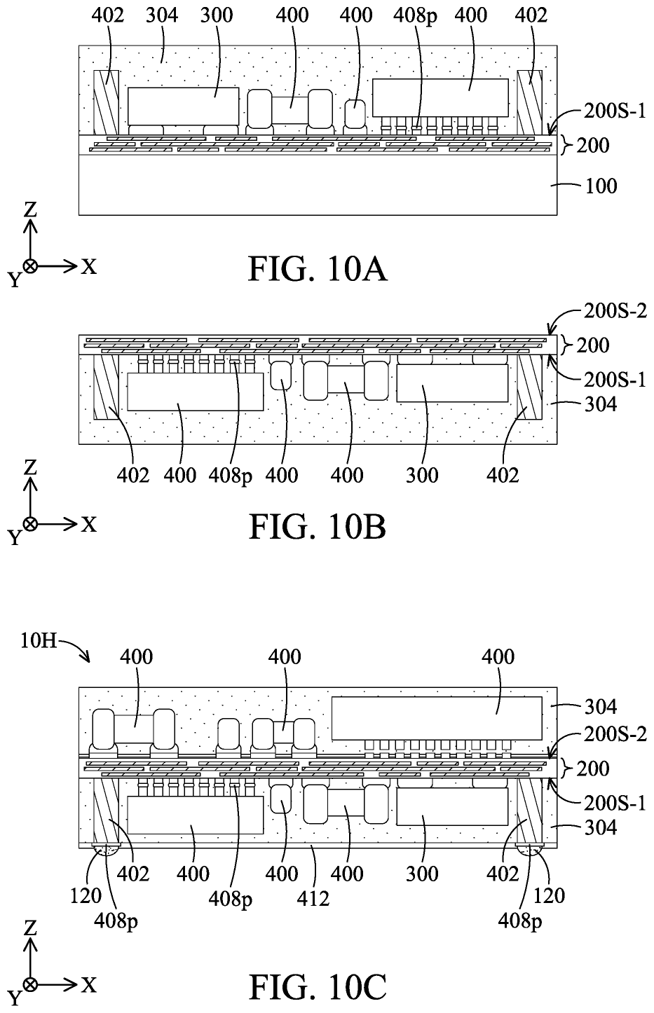

Referring to FIG. 10A, the chip 300 and/or the plurality of electronic components 400 may be bonded to the redistribution structure 200, and the redistribution structure 200 may be disposed on the substrate 100. Furthermore, the redistribution structure 200 may have a plurality of conductive elements 402. The conductive elements 402 may be adjacent to the chip 300 and/or the plurality of electronic components 400. Next, the second insulating layer 304 may be formed on the surface 200S-1 of the redistribution structure 200, and the second insulating layer 304 may cover the chip 300 and/or the plurality of electronic components 400. In accordance with some embodiments, there may be a release layer 104 (not illustrated) between the redistribution structure 200 and the substrate 100.

Referring to FIG. 10B, the release layer 104 may lose its adhesion through a laser peeling process, so that the chip 300 and electronic components 400 integrated on the redistribution structure 200 may be separated from the release layer 104 (not illustrated) and the substrate 100. Next, the substrate 100 may be removed, and the redistribution structure 200 and the chip 300 and electronic components 400 formed thereon may be flipped over to expose the surface 200S-2 of the redistribution structure 200 originally located at the bottom. In addition, the patterned conductive layer 408p may be formed with reference to the aforementioned method of manufacturing the electronic device, and the patterned conductive layer 408p may be used as an under-bump metal (UBM) layer. By designing the electronic device to have contact pads protruding from the redistribution structure 200, the bonding strength between the contact pads and the chip or electronic components may be improved, or the reliability of the electronic device may be improved, but the present disclosure is not limited thereto.

Referring to FIG. 10C, the chip 300 and/or the plurality of electronic components 400 then may be bonded to the surface 200S-2 of the redistribution structure 200, and the surface 200S-2 is opposite to the surface 200S-1. Next, the second insulating layer 304 may be formed on the surface 200S-2 of the redistribution structure 200. The second insulating layer 304 may cover the chip 300 and/or the plurality of electronic components 400. In addition, the second insulating layer 304 formed on the surface 200S-1 of the redistribution structure 200 may be removed to expose the conductive element 402, and the connection pad 120 overlapping the conductive element 402 may be formed. In accordance with some embodiments, the electronic device may further include the patterned conductive layer 408p disposed between the conductive element 402 and the connection pad 120. The patterned conductive layer 408p may be in direct contact with the conductive element 402 and the connection pad 120, forming a sandwich structure. By designing the electronic device to have contact pads protruding from the second insulating layer 304, the bonding strength between the contact pads and the chip or electronic component may be improved, or the reliability of the electronic device may be improved, but the present disclosure is not limited thereto. In accordance with some embodiments, the electronic device may further include a buffer layer 412 disposed on the surface of the second insulating layer 304. The completed electronic device 10H may be further bonded to an external component (e.g., a printed circuit board).

To summarize the above, in accordance with the embodiments of the present disclosure, the provided electronic device includes connection structures configured in a specific manner (for example, including metal pads, contact pads, and connection pads of the redistribution structure), which can alleviate excessive concentration of stress on the joint surface when the connection structures are joined, causing problems such as peeling or breakage. Therefore, the structural strength and reliability of the electronic device can be improved.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a chip;
a redistribution structure electrically connected to the chip, wherein the redistribution structure comprises a metal pad, and the metal pad is disposed opposite to the chip;
a contact pad disposed on the metal pad;
a buffer layer disposed on the redistribution structure and comprising an opening, wherein the opening exposes at least a portion of the contact pad; and
a first connection pad disposed on the contact pad and extending in the opening,
wherein in a normal direction of the chip, the metal pad, the contact pad and the first connection pad overlap.

2. The electronic device as claimed in claim 1, wherein the redistribution structure comprises a dielectric layer, the metal pad is disposed in an opening of the dielectric layer, and the top of the metal pad and a top surface of the dielectric layer are coplanar.

3. The electronic device as claimed in claim 1, further comprising:
a second connection pad disposed between the chip and the redistribution structure, wherein the chip is electrically connected to the redistribution structure through the second connection pad.

4. The electronic device as claimed in claim 1, further comprising:
a first insulating layer disposed between the chip and the redistribution structure.

5. The electronic device as claimed in claim 4, further comprising:
a second insulating layer surrounding the chip and being in contact with the first insulating layer and the redistribution structure.

6. The electronic device as claimed in claim 5, further comprising:
an electronic component adjacent to the chip and being in contact with the second insulating layer, wherein a distance between the electronic component and the chip is greater than or equal to 1 millimeter.

7. The electronic device as claimed in claim 1, wherein the contact pad has a curved surface.

8. The electronic device as claimed in claim 1, further comprising:
an intermediate layer, wherein at least a portion of the intermediate layer is disposed between the contact pad and the first connection pad.

9. The electronic device as claimed in claim 8, wherein the intermediate layer has a curved surface.

10. The electronic device as claimed in claim 8, wherein a width of the contact pad is greater than or equal to a width of the intermediate layer.

11. The electronic device as claimed in claim 1, wherein a surface of the contact pad has a plurality of recesses.

12. The electronic device as claimed in claim 1, wherein a top surface of the contact pad and a top surface of the buffer layer are non-coplanar.

13. The electronic device as claimed in claim 12, wherein the top surface of the contact pad is lower than the top surface of the buffer layer.

14. The electronic device as claimed in claim 1, wherein the first connection pad covers at least a portion of a side surface of the contact pad.

15. A method of manufacturing an electronic device, comprising:
providing a substrate;
forming a redistribution structure on the substrate, the redistribution structure comprising a metal pad;
forming a chip on the redistribution structure, wherein the metal pad is disposed opposite to the chip;
removing the substrate and flipping over the redistribution structure and the chip formed thereon;
forming a contact pad on the metal pad;
forming a buffer layer on the redistribution structure, and forming an opening in the buffer layer, wherein the opening exposes at least a portion of the contact pad; and
forming a first connection pad on the contact pad and extending in the opening,
wherein in a normal direction of the chip, the metal pad, the contact pad and the first connection pad overlap.

16. The method of manufacturing an electronic device as claimed in claim 15, wherein the step of forming the redistribution structure on the substrate comprises:
forming a dielectric layer;
forming an opening in the dielectric layer; and
forming the metal pad in the opening of the dielectric layer.

17. The method of manufacturing an electronic device as claimed in claim 15, further comprising:
forming a second connection pad between the chip and the redistribution structure, wherein the chip is electrically connected to the redistribution structure through the second connection pad.

18. The method of manufacturing an electronic device as claimed in claim 15, further comprising:
forming a first insulating layer between the chip and the redistribution structure; and
forming a second insulating layer surrounding the chip, wherein the second insulating layer is in contact with the first insulating layer and the redistribution structure.

19. The method of manufacturing an electronic device as claimed in claim 15, wherein in the step of forming the first connection pad on the contact pad and extending in the opening, the first connection pad and the contact pad react to form an intermediate layer, and at least a portion of the intermediate layer is disposed between the contact pad and the first connection pad.

20. The method of manufacturing an electronic device as claimed in claim 15, wherein the step of forming the contact pad on the metal pad comprises:
forming a conductive layer on the substrate; and
after removing the substrate and flipping over the redistribution structure and the chip formed thereon, patterning the conductive layer to form the contact pad.
